(19) United States
(12) Patent Application Publication
(10) Pub. No.: US 2023/0245950 A1
(43) Pub. Date: Aug. 3, 2023

(54) HEAT DISSIPATING SYSTEM FOR ELECTRONIC DEVICES

(71) Applicant: ADEIA SEMICONDUCTOR BONDING TECHNOLOGIES INC., San Jose, CA (US)

(72) Inventors: Belgacem HABA, Saratoga, CA (US); Patrick VARIOT, Los Gatos, CA (US); Rajesh KATKAR, Milpitas, CA (US); Hong SHEN, Palo Alto, CA (US)

(21) Appl. No.: 18/160,979

(22) Filed: Jan. 27, 2023

Related U.S. Application Data
(60) Provisional application No. 63/305,112, filed on Jan. 31, 2022.

(51) Int. Cl. H01L 23/44; F28F 13/12; H10B 80/00; H01L 23/38; H01L 25/065; H01L 23/00; H01L 23/467

(52) U.S. Cl. CPC H01L 23/44; F28F 13/12; H10B 80/00; H01L 23/38; H01L 25/0655; H01L 24/05; H01L 24/08; H01L 23/467; H01L 2224/08225; H01L 2224/05647

(57) ABSTRACT

An integrated device package is disclosed. The integrated device package can include a carrier, and a cap bonded to the carrier. The carrier and the cap at least partially define a cavity that is configured to receive a coolant. The integrated device package can include an inorganic material layer disposed at least on a portion of the carrier. At least a portion of the inorganic material layer is exposed to the cavity and configured to contact the coolant. The cap can be directly bonded to the carrier without an intervening adhesive. The integrated device package can include an integrated device die that is disposed in the cavity and bonded to the carrier. The integrated device die can be directly bonded to the carrier without an intervening adhesive.

### CROSS-REFERENCE TO RELATED APPLICATIONS

This application claims priority to U.S. Provisional Patent Application No. 63/305,112, filed Jan. 31, 2022, the entire contents of which are hereby incorporated by reference herein in their entirety and for all purposes.

### BACKGROUND

### Field

The field relates to dissipating heat in microelectronics.

### Description of the Related Art

An integrated device package can include electrical components (e.g., integrated device dies, passive components such as inductors, resistors, and capacitors, etc.). Electrical components generate heat during operation. Certain high performance applications involve high power components that generate very large amount of heat. It can be important to transfer the generated heat out of the package for sustained reliable operation. Accordingly, there remains a continuing need for improved heat dissipating/transfer system for electronic devices and integrated device packages.

### BRIEF DESCRIPTION OF THE DRAWINGS

Specific implementations will now be described with reference to the following drawings, which are provided by way of example, and not limitation.

FIG. 1 is a schematic cross-sectional side view of a cooling system configured to dissipate heat generated by integrated device dies mounted to a package substrate.

FIG. 2 is a cross-sectional side view of an integrated device package, according to an embodiment.

FIG. 3 is a cross-sectional side view of an integrated device package having a flow disturbance structure, according to an embodiment.

FIG. 4 is a cross-sectional side view of a cooling system having a heat sink coupled to a cap, according to an embodiment.

FIG. 5 is a cross-sectional side view of a cooling system having a circulation pipe, according to an embodiment.

FIG. 6 is a cross-sectional side view of a cooling system having the heat sink and the circulation pipe, according to an embodiment.

FIG. 7 is a cross-sectional side view of a cooling system having a thermoelectric element coupled to the cap, according to an embodiment.

FIG. 8 is a cross-sectional side view of a cooling system having thermoelectric elements coupled to dies, according to an embodiment.

FIG. 9 is a cross-sectional side view of a cooling system having thermoelectric elements coupled to dies and the circulation pipe, according to an embodiment.

### DETAILED DESCRIPTION

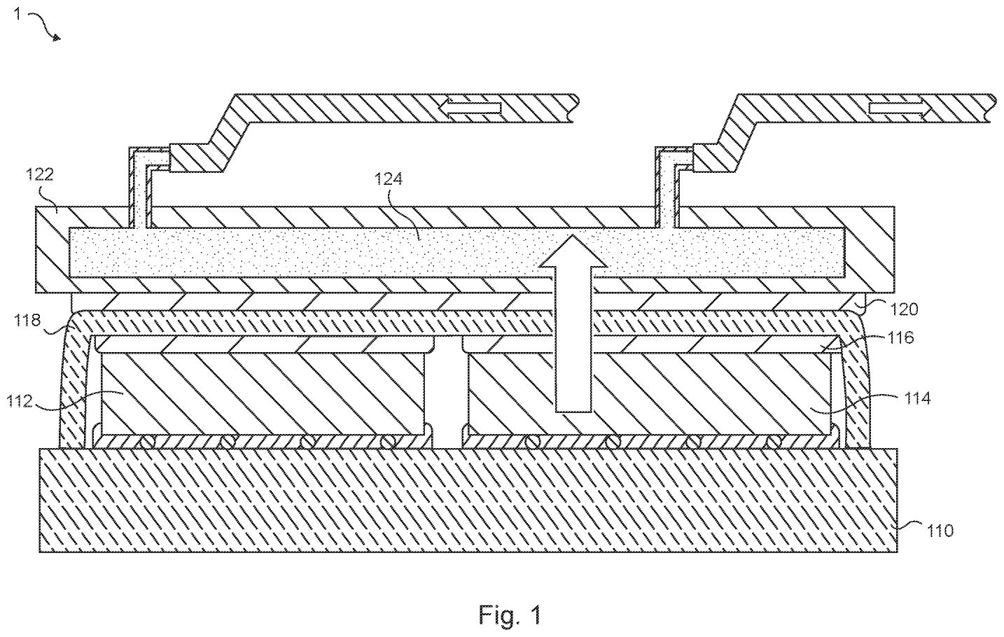

FIG. 1 is a schematic cross-sectional side view of a cooling system 1 configured to dissipate heat generated by integrated device dies (a first chip 112 and a second chip 114) mounted to a package substrate 110. The cooling system 1 includes a first thermal interface material (TIM) 116, a heat spreader 118, a second TIM 120, and a liquid pipe 122 in which a coolant 124 is disposed. As shown by an arrow in FIG. 1, the heat generated by the first chip 112 and the second chip 114 is transferred through the first TIM 116, the heat spreader 118, and the second TIM 120, to the liquid pipe 122. The first TIM 116, the heat spreader 118, and the second TIM 120 may be less efficient at dissipating heat as compared to the liquid pipe 122. Therefore, it can be desirable to have the liquid pipe 122 closer to the first chip 112 and the second chip 114, and/or to eliminate the first TIM 116, the heat spreader 118, and the second TIM 120 so as to improve the effectiveness of heat transfer away from the chips 112, 114.

Various embodiments disclosed herein allow the coolant to be in contact (e.g., in direct thermal and/or physical contact) with a heat source, such as the first chip 112 and the second chip 114. In such embodiments, the heat generated by the heat source can be dissipated more efficiently as compared to having the heat transferred to the first TIM 116, the heat spreader 118, and the second TIM 120 and eventually to the liquid pipe 122. For example, the heat generated by the heat source can be dissipated directly by the liquid pipe 122. However, when the coolant 124 is provided so as to directly contact the heat source, the coolant 124 may damage the heat source (e.g., the first chip 112 and the second chip 114). For example, if an integrated device die were mounted on a package substrate and coolant were provided so as to directly contact the integrated device die, the coolant may seep in and out at or near an interface between the integrated device die and the package substrate, e.g., between solder balls for flip chip mounted components.

Various embodiments of the present disclosure relate to heat dissipation systems for integrated device packages. In various embodiments, a heat generating element (e.g., an integrated device die) can be bonded to a carrier using a hybrid direct bonding technique. Two or more elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure.

In some embodiments, elements (e.g., a semiconductor element and a carrier) are directly bonded to one another without an adhesive. In various embodiments, a non-conductive (e.g., semiconductor or inorganic dielectric) material of a first element can be directly bonded to a corresponding non-conductive (e.g., semiconductor or inorganic dielectric) field region of a second element without an adhesive. In various embodiments, a conductive feature or region (e.g., a metal pad) of the first element can be directly bonded to a corresponding conductive feature or region (e.g., a metal pad) of the second element without an adhesive. The non-conductive material can be referred to as a nonconductive bonding region or bonding layer of the first element. In some embodiments, the non-conductive material of the first element can be directly bonded to the corresponding non-conductive material of the second element using bonding techniques without an adhesive using the direct bonding techniques disclosed at least in U.S. Pat. Nos. 9,564,414; 9,391,143; and 10,434,749, the entire contents of each of which are incorporated by reference herein in their entirety and for all purposes. In other applications, in a bonded structure, a non-conductive material of a first element can be directly bonded to a conductive material of a second element, such that a conductive material of the first element is intimately mated with a non-conductive material of the second element. Suitable dielectric materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon. Such carbon-containing ceramic materials can be considered inorganic, despite the inclusion of carbon, unlike primarily hydrocarbon materials. In some embodiments, the dielectric materials do not comprise polymer materials, such as epoxy, resin or molding materials. Additional examples of hybrid direct bonding may be found throughout U.S. Pat. No. 11,056,390, the entire contents of which are incorporated by reference herein in their entirety and for all purposes.

In various embodiments, direct bonds can be formed without an intervening adhesive. For example, semiconductor or dielectric bonding surfaces can be polished to a high degree of smoothness. The nonconductive bonding surfaces can be polished using, for example, chemical mechanical polishing (CMP). The roughness of the polished bonding surfaces can be less than 30 Å rms. For example, the roughness of the bonding surfaces can be in a range of about 0.1 Å rms to 15 Å rms, 0.5 Å rms to 10 Å rms, or 1 Å rms to 5 Å rms. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two non-conductive materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished bonding surfaces can be slightly rougher (e.g., about 1 Å rms to 30 Å rms, 3 Å rms to 20 Å rms, or possibly rougher) after an activation process.

In various embodiments, conductive contact pads of the first element can also be directly bonded to corresponding conductive contact pads of the second element. For example, a direct hybrid bonding technique can be used to provide conductor-to-conductor direct bonds along a bond interface that includes covalently direct bonded dielectric-to-dielectric (e.g., dielectric-to-dielectric) surfaces, prepared as described above. In various embodiments, the conductor-to-conductor (e.g., conductive feature to conductive feature) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. The bond structures described herein can also be useful for direct metal bonding without non-conductive region bonding, or for other bonding techniques.

In some embodiments, non-conductive (e.g., dielectric) bonding surfaces (for example, inorganic dielectric surfaces) can be prepared and directly bonded to one another without an intervening adhesive as explained above. Conductive contact features (which may be surrounded by nonconductive dielectric field regions) may also directly bond to one another without an intervening adhesive. In some embodiments, the respective contact features can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand with respect to the nonconductive bonding regions and contact one another to form a metal-to-metal direct bond. The bonded structure can be annealed at an anneal temperature over 250° C. For example, the anneal temperature can be over 300° C. or 350° C. The anneal temperature can be determined based at least in part on the material of the conductive contact pads, coefficient of thermal expansion (CTE) mismatch between the conductive contact pads and the nonconductive bonding regions, the gap between the conductive contact pads. Beneficially, the use of surface to surface direct bonding techniques without adhesive, such as “ZIBOND®,” and/or the use of hybrid bonding techniques, such as Direct Bond Interconnect, or DBI®, available commercially from Adeia of San Jose, Calif., can enable high density of pads connected across the direct bond interface (e.g., small or fine pitches for regular arrays). In various embodiments, the contact pads can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer). The embodiments disclosed herein can accordingly apply to wafer-to-wafer (W2 W), die-to-die (D2D), or die-to-wafer (D2 W) bonding processes. In wafer-to-wafer (W2 W) processes, two or more wafers can be directly bonded to one another (e.g., direct hybrid bonded) and subsequently singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements can be directly bonded to one another without an adhesive, which is different from a deposition process and results in a structurally different interface compared to a deposition. In one application, a width of the first element in the bonded structure is similar to a width of the second element. In some other embodiments, a width of the first element in the bonded structure is different from a width of the second element. Similarly, the width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanometer-scale voids (nanovoids) are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

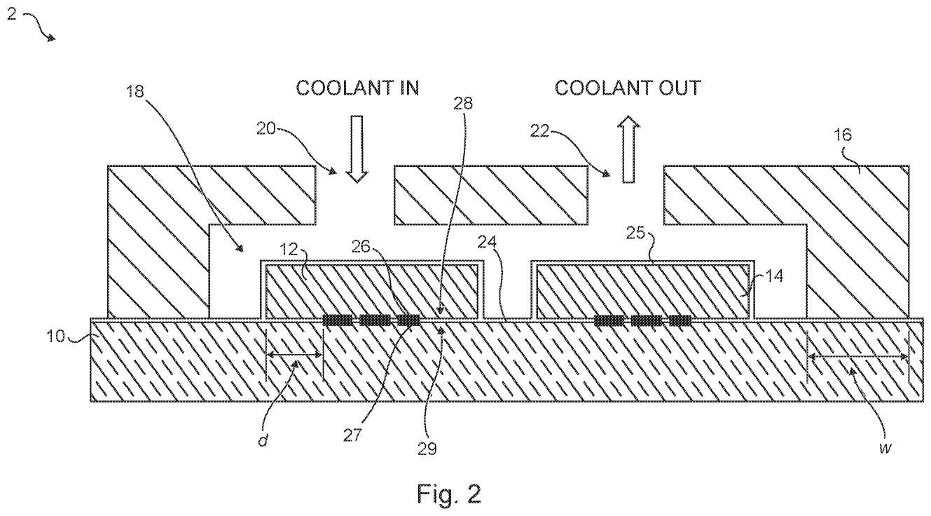

FIG. 2 is a cross-sectional side view of an integrated device package 2 according to an embodiment. The integrated device package 2 can include a carrier 10, a first die 12 mounted to the carrier 10, a second die 14 mounted to the carrier 10, and a cap 16 coupled to the carrier 10. The carrier 10 and the cap 16 can at least partially define a cavity 18 to which the first die 12 and the second die 14 are disposed. The cavity 18 is configured to receive a coolant (not shown). The cap 16 can comprise openings (e.g., a coolant inlet 20 and a coolant outlet 22) for the coolant to be supplied to or removed out of the cavity 18. The coolant can comprise any suitable refrigerant material. For example, the coolant can comprise a fluid coolant, such as a liquid coolant (such as a dielectric liquid) or a gas (such as air or an inactive gas). In some embodiments, the coolant can have a thermal conductivity of at least 0.1 W/mK at a temperature of 20° C. For example, the coolant can have a thermal conductivity of at least 0.5 W/mK at a temperature of 20° C. In some embodiments, the thermal conductivity of the coolant can be in a range of 0.1 W/mK to 10 W/mK, 0.1 W/mK to 5 W/mK, 00.1 W/mK to 3 W/mK, 0.5 W/mK to 5 W/mK, or 0.5 W/mK to 3 W/mK at a temperature of 20° C.

In some embodiments, the carrier 10 can comprise an inorganic material layer 24. The inorganic material layer 24 can be a part of the carrier 10, or a separate layer disposed at least partially on the carrier 10. In some embodiments, the inorganic material layer 24 can serve as a nonconductive bonding layer to which the cap 16 and/or the dies 12, 14 can be directly bonded (e.g., directly hybrid bonded). In such embodiments, at least a portion of the inorganic material layer 24 can be disposed between the carrier 10 and the dies 12, 14. The inorganic material layer 24 can prevent or mitigate contaminating the bonding interface between the die 12, 14 and the carrier 10 by the coolant. Accordingly, the inorganic material layer 24 can comprise any suitable protective layer, such as silicon oxide, silicon nitride, titanium nitride, or any other suitable direct bonding material described herein. In some embodiments, the protective layer can comprise a multi-layer protective coating. In some embodiments, an inorganic material layer 25 can also be disposed on surfaces of the first and second die 12, 14. In some embodiments, the inorganic material layer 25 can comprise a material that is the same as or generally similar to the material of the inorganic material layer 24. In some embodiments, the carrier 10 can comprise a semiconductor element, such as an interposer, an integrated device die, or other element. In other embodiments, the carrier 10 can comprise a package substrate (e.g., a printed circuit board (PCB)). In some embodiments, the carrier 10 can be mounted on and/or electrically coupled to a package substrate (not shown). The inorganic material layer 24 can have a thickness in a range of 10 nm to 5 μm, 10 nm to 1 μm, or 50 nm to 1 μm.

In some embodiments, the first die 12 and/or the second die 14 can comprise a memory die (e.g., a dynamic random-access memory (DRAM) die), a logic die, a sensor die, a microelectromechanical systems (MEMS) die, a processor die (e.g., graphics processing unit (GPU) die), or any other suitable type of semiconductor element. In some embodiments, the first die 12 and/or the second die 14 can be directly bonded to the carrier 10 without an intervening adhesive, such as by way of any one or more direct bonding techniques described above. For example, the first die 12 can comprise a conductive feature 26 that is directly bonded to a corresponding conductive feature 27 of the carrier 10, and a non-conductive region 28 that is directly bonded to a corresponding non-conductive region 29 of the carrier 10 (e.g., to the inorganic material layer 24). In some other embodiments, the first die 12 and/or the second die 14 can be flip-chip mounted to the carrier 10 with an adhesive, such as solder (not shown). In some embodiments, a distance d between the conductive feature 26 and an edge of the first die 12 can be in a range of 100 μm to 500 μm, 200 μm to 500 μm, 300 μm to 500 μm, 100 μm to 400 μm, 100 μm to 300 μm, or 200 μm to 400 μm.

Although first and second dies 12, 14 are shown to be bonded to the carrier 10, another embodiment may have only one die bonded to the carrier 10. In some other embodiments, the integrated device package 2 can include three or more dies bonded to the carrier 10. In some embodiments, a plurality of dies may be stacked on the carrier 10. In some embodiments, the first die 12 and/or the second die 14 may comprise an active die or a passive die.

The cap 16 can comprise any suitable material, such as silicon, glass, ceramic, plastic, metal, etc. In some embodiments, the cap 16 can be directly bonded to the carrier 10 without an intervening adhesive, such as by way of any one or more direct bonding techniques described above. In some other embodiments, the cap 16 can be bonded to the carrier 10 by way of an adhesive, such as a glue or solder. In some embodiments, the cap 16 and the carrier 10 can include corresponding metal portions, and the metal portions of the cap 16 and the carrier 10 can be bonded in any suitable manner disclosed herein. During operation of a cooling or heat dissipation system utilizing the integrated device package 2, the cavity 18 can be at least partially filled with the fluid coolant (not shown), which can comprise a liquid coolant or a gas coolant. In some embodiments, the cavity 18 can be completely filled with the coolant. In some embodiments, a width w of a leg of the cap 16 can be in a range of 100 μm to 500 μm, 200 μm to 500 μm, 300 μm to 500 μm, 100 μm to 400 μm, 100 μm to 300 μm, or 200 μm to 400 μm. The coolant inlet 20 and the coolant outlet 22 of the cap 16 can be coupled to, for example, a system (not shown) that drives the coolant. The locations of the coolant inlet 20 and the coolant outlet 22 can be selected based at least in part on locations of the heat generating component (e.g., the first and second dies 12, 14), and/or fluid dynamics of the coolant in the cavity 18.

In some embodiments, portions within the cavity 18 configured to be exposed to the fluid coolant (e.g., internal side and/or upper walls of the cap 16, surfaces of first die 12 and/or second die 14, surfaces of the carrier 10) may be covered with an organic or inorganic (but possibly thermally conductive) protective coating(s). In such instances, the fluid coolant may directly contact the protective coating(s) (e.g., the inorganic material layer 25).

When the first and second dies 12, 14 are directly bonded (e.g., directly hybrid bonded) to the carrier 10 as described above, electrical connections between the first and second dies and the carrier 10 can be protected. For example, the bonding interface between the first and second dies 12, 14 and the carrier 10 can prevent or mitigate the coolant from seeping, penetrating, or leaking into the bonding interface thereby protecting the circuitry in the first and second dies 12, 14. When the cap 16 is directly bonded to the carrier 10 as described above, leakage of the coolant from the cavity 18 to outside of the cavity 18 can be prevented or mitigated. The inorganic material layer 25 on the surfaces of the first and second dies 12, 14 can protect the first and second dies 12, 14 from being damaged by the coolant. In some embodiments, the inorganic material layer 25 can at least partially encapsulate the first and second dies 12, 14. For example, the inorganic material layer 25 may only a portion of the first die 12 or the second die 14. For another example, the inorganic material layer 25 can completely encapsulate the first and/or second die(s) 12, 14. The inorganic material layer 25 can be relatively thin such that the heat can be transferred from the first and/or second die(s) 12, 14 to the coolant without significant loss. For example, the inorganic material layer 25 can have a thickness in a range of 10 nm to 5 μm, 10 nm to 1 μm, or 50 nm to 1 μm. In some embodiments, the thickness of the inorganic material layer 25 can be thinner along a sidewall of the first die 12 or the second die 14 than along a top side of the first die 12 or the second die 14.

In some embodiments, the first and/or second die 12, 14 can comprise an arrestor (not shown). The arrestor may include a physical cavity that is configured to collect leaked or seeped coolant, or an absorbant that absorbs leaked or seeped coolant to prevent or mitigate the coolant from leaking into the bonding interface. Similarly, the cap 16 can comprise an arrestor (not shown) that is configured to increase the sealing reliability between the cap 16 and the carrier 10. The arrestor can prevent or mitigate the coolant from leaking outside the cavity 18.

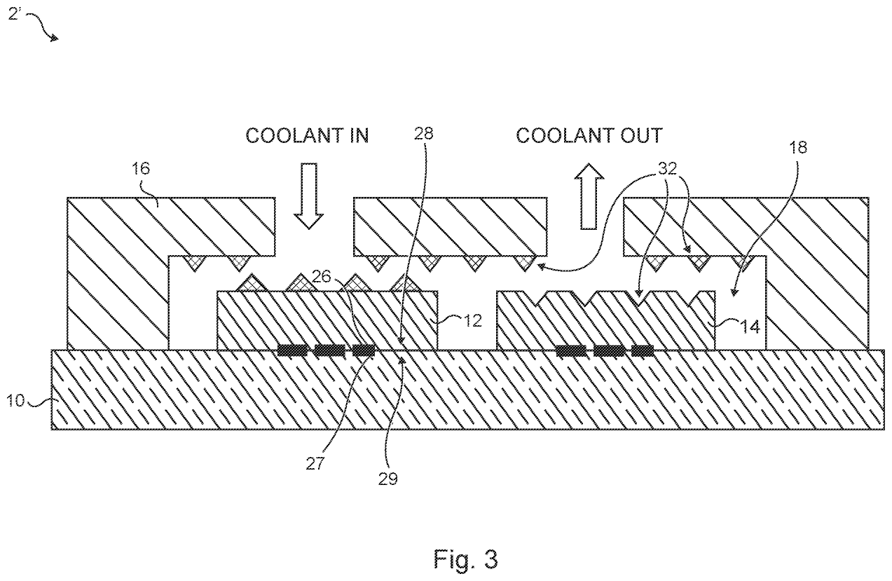

FIG. 3 is a cross-sectional side view of an integrated device package 2′ according to an embodiment. Unless otherwise noted, the components of FIG. 3 may be the same as or generally similar to like components disclosed herein, such as those of FIG. 2. The integrated device package 2′ is generally similar to the integrated device package 2 illustrated in FIG. 2, except the integrated device package 2′ includes a flow disturbance structure 32. For example, protrusions can be provided in the cavity 18 on inner surfaces of the cap 16 and/or on surfaces of the first and second dies 12, 14. In some embodiments, the flow disturbance structure 32 can also be provided on a surface of the carrier 10 in the cavity 18. In some embodiments, the flow disturbance structure 32 can be formed by removing at least a portion of the first or second die 12, 14 and/or the cap 16. During operation of a cooling or heat dissipation system utilizing the integrated device package 2′, the coolant can flow in the cavity 18. The flow disturbance structure 32 can disturb the flow of the coolant so as to enhance heat transfer of the heat generated by the first and second die 12, 14 to the coolant.

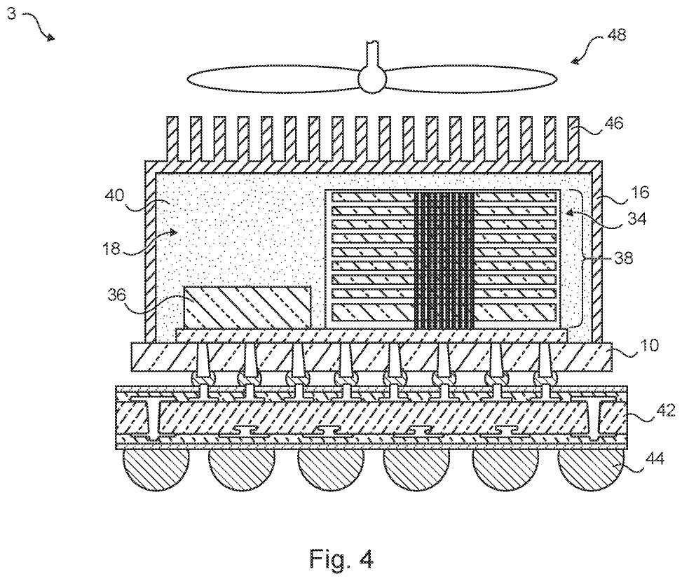

FIGS. 4-9 are schematic cross-sectional side views of cooling systems 3, 4, 5, 6, 7, 8 according to various embodiments. FIGS. 4-9 show a heat source 34 that includes a die 36 mounted on the carrier 10 and a plurality of stacked dies 38 mounted on the carrier 10, a cap 16 coupled to the carrier 10, a coolant 40 disposed in a cavity 18 at least partially defined by the carrier 10 and the cap 16, and a package substrate 42 to which the carrier 10 is mounted. In some embodiments, the die 36 and the plurality of stacked dies 38 can be directly bonded (e.g., directly hybrid bonded) to the carrier 10 as disclosed herein. The package substrate 42 can be mounted to a larger system or device (not shown), for example, by way of a plurality of solder balls 44. In the illustrated embodiment, the stacked dies 38 can comprise a plurality of memory dies, and the die 36 can comprise a processor die configured to communicate with the stacked dies 38. In some embodiments, the plurality of memory dies can be directly bonded (e.g., directly hybrid bonded) to one another as disclosed herein. Any suitable combinations of the principles and advantages disclosed herein can be used.

The cap 16 of the cooling system 3 shown in FIG. 4 includes a heat sink 46 (e.g., a plurality of fins) and a fan 48. The heat sink 46 can enable the heat generated by the heat source 34 to dissipate out of the cooling system 3. In some embodiments, the coolant 40 can be enclosed in the cavity 18. In the embodiment illustrated in FIG. 4, the fluid coolant 40 may be confined to the cavity 18 such that, in operation, coolant does not flow into and out of the cavity, but rather remains in the cavity 18. The heat sink 46 can remove heat from the coolant 40, with the fan 48 imparting convective heat transfer away from the heat sink 46.

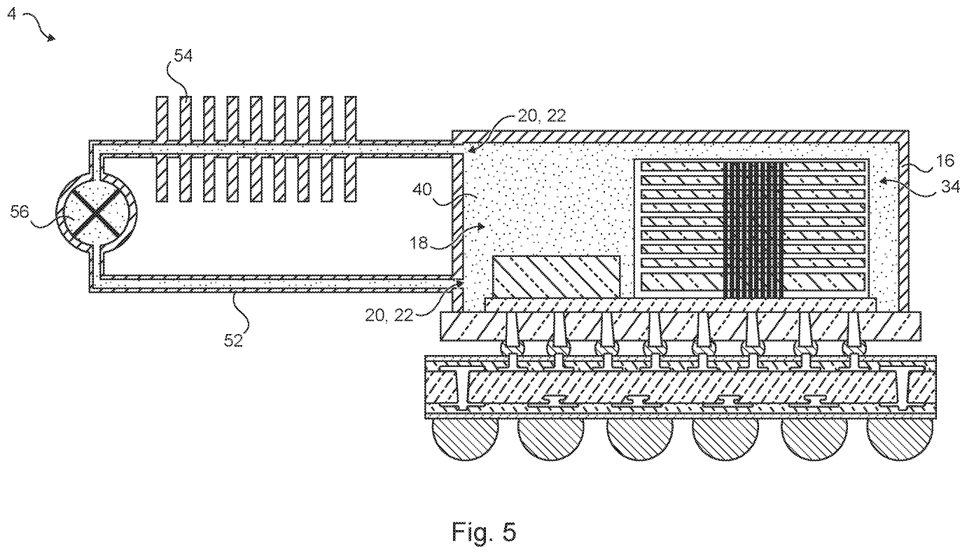

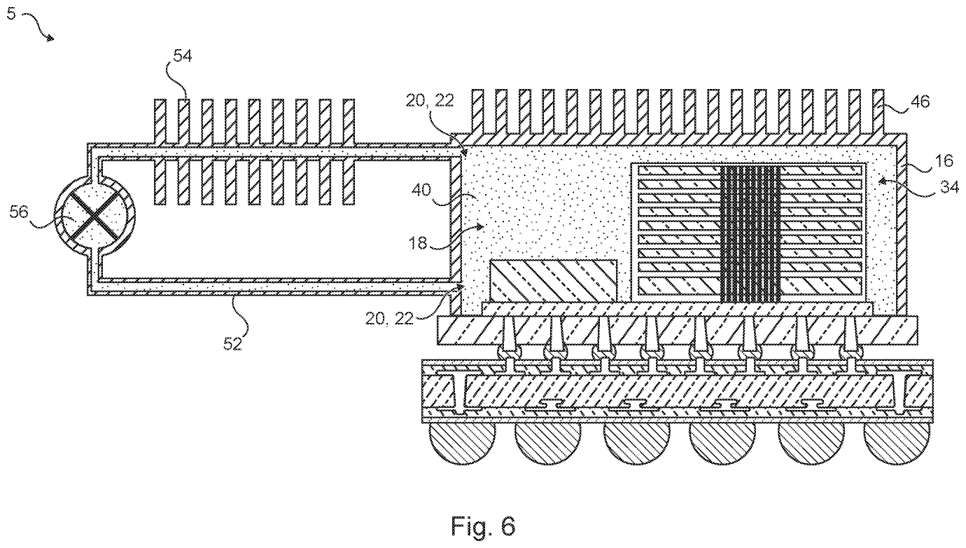

The cap 16 of the cooling system 4 shown in FIG. 5 includes a fluid or coolant inlet 20 and a fluid or coolant outlet 22. A circulation pipe 52 can be coupled to the coolant inlet 20 and outlet 22. The coolant inlet 20 can be configured to convey the coolant 40 into the cavity 18, and the coolant outlet 22 can be configured to remove the coolant 40 from the cavity 18. The circulation pipe 52 can comprise a heat sink 54 (a plurality of fins) coupled thereto. A coolant driver 56 can be disposed in a flow path in the circulation pipe 52. The coolant driver 56 can comprise a pump. The coolant driver 56 can drive the coolant 40 into and/or out of the cavity 18 through the circulation pipe 52. In some embodiments, as in the cooling system 3 of FIG. 4, the cooling system 4 can also include a fan (not shown). As shown in FIG. 6, a cooling system 5 can utilize the heat sink 46 and the heat sink 54 together.

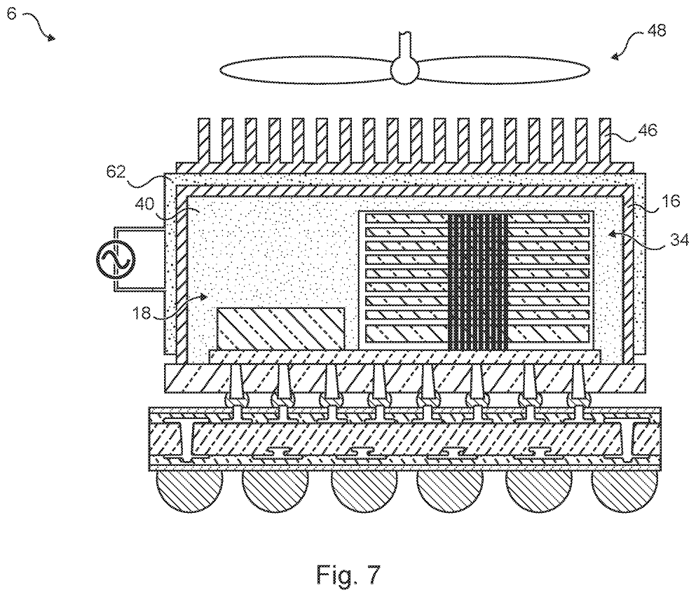

As shown in FIG. 7, a cooling system 6 can include a thermoelectric element 62, such as a thermoelectric effect or Peltier effect element, that is coupled to the cap 16. Voltage can be applied to the thermoelectric element 62 to facilitate thermal transfer from one side of the thermalelectric element 62 to the other side of the thermalelectric element 62. The thermoelectric element 62 can convert the heat transferred to the thermoelectric element 62 to electric voltage thereby reducing the temperature of the coolant 40 in the cavity. The cooling system 6 can also include a heat sink 46 coupled to the cap 16. In the illustrated embodiment, a portion of the thermoelectric element 62 is disposed between the cap 16 and the heat sink 46.

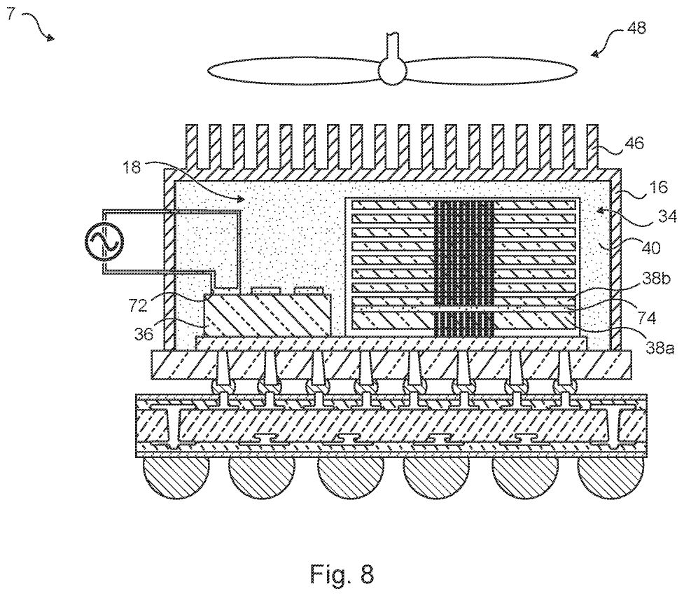

As shown in FIG. 8, a cooling system 7 can include a thermoelectric element 72 coupled to the die 36 (e.g., a graphics processing unit die, or GPU die) and a thermoelectric element 74 positioned between a die 38a (e.g., a logic die) and a die 38b (e.g., a DRAM die). A side of the thermoelectric element 72 that is coupled to the die 36 can be a hot side and the other side of the thermoelectric element 72 can be a cold side. The thermoelectric elements 72, 74 can be configured to convey heat away from the dies 36, 38a, 38b and into the coolant 40. Additional examples of incorporating thermoelectric elements into directly bonded structures are shown and described throughout U.S. patent application Ser. No. 18/067,655, titled “THERMOELECTRIC COOLING FOR DIE PACKAGES,” filed Dec. 16, 2022, the entire contents of which are hereby incorporated by reference in their entirety and for all purposes.

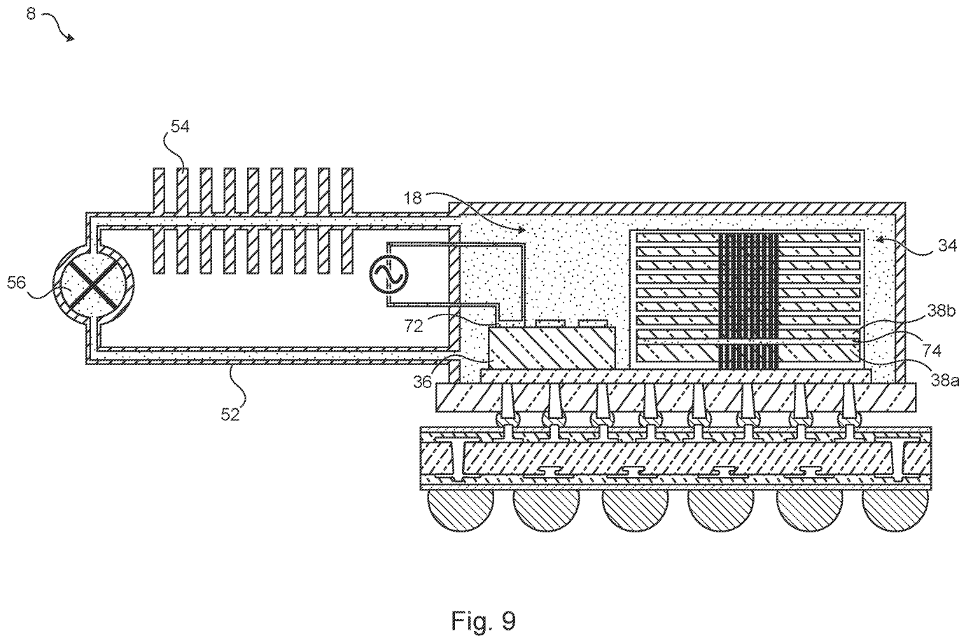

As shown in FIG. 9, a cooling system 8 can utilize the heat sink 54 shown in FIG. 5 and the thermoelectric elements 72, 74 shown in FIG. 8 together. The cooling system 8 can include the thermoelectric element 72 over the die 36, the thermoelectric element 74 between a die 38a (e.g., a logic die) and a die 38b (e.g., a DRAM die), and the circulation pipe 52 in fluidic communication with the cavity 18.

Any suitable combinations of the principles and advantages disclosed herein can be used. For example, any suitable combinations of features shown in FIGS. 2-9 can be implemented in together in a cooling system.

In one aspect, an integrated device package is disclosed. The integrated device package can include a carrier, and a cap that is directly bonded to the carrier without an intervening adhesive. The carrier and the cap at least partially define a cavity that is configured to receive a coolant. The integrated device package can include an inorganic material layer that is disposed at least on a portion of the carrier. At least a portion of the inorganic material layer is exposed to the cavity and configured to contact the coolant.

In one embodiment, the package further includes an integrated device die that is disposed in the cavity and bonded to the carrier. The carrier can include an interposer. The carrier can include a printed circuit board (PCB). The cap can include silicon, glass, plastic, or metal. The cap can be bonded to the carrier by way of a glue, eutectic, or solder. The inorganic material layer can be further disposed on the integrated device die. The integrated device die can be directly bonded to the carrier. The integrated device die can include a conductive feature and a non-conductive region. The conductive feature can be directly bonded to a corresponding conductive feature of the carrier and the non-conductive region can be directly bonded to a corresponding non-conductive region of the carrier. A distance between the conductive feature of the integrated device die and an edge of the integrated device die can be between 50 μm to 500 μm. The non-conductive region of the carrier can include the inorganic material layer. The integrated device die can be a memory die or a logic die. The package can further include a second integrated device die that is stacked on the integrated device die. The integrated device die can be configured to contact the coolant. The cap can include a coolant inlet and a coolant outlet. The coolant can be configured to flow from the coolant inlet to the coolant outlet in the cavity. The coolant inlet and the coolant outlet can be coupled to a pump. A leg of the cap that is bonded to the carrier can have a width in a range of 100 μm to 5 mm. The coolant can include a liquid or a gas. The cap can include a heat sink that includes a plurality of fins. The package can further include a flow disturbance structure on the integrated device die or on an inner surface of the cap configured to disturb flow of the coolant in the cavity. The package can further include a thermoelectric element that is coupled to the cap or the integrated device die. The package can further include a second integrated device die that is disposed in the cavity. The second integrated device die can be directly bonded to the carrier. The second integrated device die can be stacked on the integrated device die.

In one embodiment, the coolant is disposed in the cavity at least during operation of the integrated device package, and at least a portion of the inorganic material layer is in contact with the coolant at least during operation of the integrated device package.

In one aspect, an integrated device package is disclosed. The integrated device package can include a carrier, and a cap that is bonded to the carrier. The carrier and the cap at least partially define a cavity that is configured to receive a fluid coolant. The integrated device package can include an opening that is configured to convey the fluid coolant into or remove the fluid coolant from the cavity. The integrated device package can include an integrated device die that is disposed in the cavity and directly bonded to the carrier.

In one embodiment, the package further includes an inorganic material layer disposed at least on a portion of the carrier, wherein the inorganic material is configured to contact the fluid coolant.

In one embodiment, the carrier includes an interposer.

In one embodiment, the carrier includes a printed circuit board (PCB).

In one embodiment, the cap includes silicon, glass, plastic, or metal.

In one embodiment, the cap is directly bonded to the carrier without an intervening adhesive.

In one embodiment, the cap is bonded to the carrier by way of a glue or solder.

In one embodiment, the package further includes an inorganic material layer that is disposed on the integrated device die.

In one embodiment, the integrated device die includes a conductive feature and a non-conductive region. The conductive feature can be directly bonded to a corresponding conductive feature of the carrier and the non-conductive region can be directly bonded to a corresponding non-conductive region of the carrier. A distance between the conductive feature to an edge of the integrated device die can be between 100 μm to 500 μm.

In one embodiment, the integrated device die is a memory die or a logic die.

In one embodiment, the integrated device die is configured to contact the fluid coolant.

In one embodiment, the package further includes a second opening. The opening can include a fluid inlet that is configured to convey the fluid coolant into the cavity, and the second opening can include a fluid outlet that is configured to remove the fluid coolant from the cavity. The cap can include the fluid inlet and the fluid outlet. The fluid coolant can be configured to flow from the coolant inlet to the coolant outlet in the cavity. The coolant inlet and the coolant outlet can be coupled to a pump.

In one embodiment, a leg of the cap that is bonded to the carrier has a width in a range of 100 μm to 500 μm.

In one embodiment, the fluid coolant includes a liquid or a gas.

In one embodiment, the cap includes a heat sink that includes a plurality of fins.

In one embodiment, the package further includes a flow disturbance structure on the integrated device die or on an inner surface of the cap that is configured to disturb flow of the fluid coolant in the cavity.

In one embodiment, the package further includes a thermoelectric element that is coupled to the cap or the integrated device die.

In one embodiment, the package further includes a second integrated device die disposed in the cavity. The second integrated device die can be directly bonded to the carrier. The second integrated device die can be stacked on the integrated device die.

In one aspect, a heat dissipation system is disclosed. The heat dissipation system can include a carrier, and a cap that is bonded to the carrier. The carrier and the cap at least partially define a cavity. The heat dissipation system can include a fluid coolant that is disposed in the cavity, and an integrated device die that is disposed in the cavity and directly bonded to the carrier.

In one embodiment, the system further includes an inorganic material layer that is disposed at least on a portion of the carrier. The inorganic material layer can be in contact with the fluid coolant.

In one embodiment, the carrier includes an interposer.

In one embodiment, the carrier includes a printed circuit board (PCB).

In one embodiment, the cap includes silicon, glass, plastic, or metal.

In one embodiment, the cap is directly bonded to the carrier without an intervening adhesive.

In one embodiment, the cap is bonded to the carrier by way of a glue or solder.

In one embodiment, the system further includes an inorganic material layer that is disposed on the integrated device die.

In one embodiment, the integrated device die is directly bonded to the carrier. The integrated device die can include a conductive feature and a non-conductive region. The conductive feature can be directly bonded to a corresponding conductive feature of the carrier and the non-conductive region can be directly bonded to a corresponding non-conductive region of the carrier. A distance between the conductive feature to an edge of the integrated device die can be between 50 μm to 500 μm. The non-conductive region of the carrier can include an inorganic material layer.

In one embodiment, the integrated device die is a memory die or a logic die.

In one embodiment, the integrated device die is contacts the fluid coolant.

In one embodiment, the cap includes a coolant inlet and a coolant outlet. The fluid coolant can flow from the coolant inlet to the coolant outlet in the cavity. The system can further include a pump that is coupled to the coolant inlet and the coolant outlet, and configured to drive the fluid coolant.

In one embodiment, a leg of the cap that is bonded to the carrier has a width in a range of 100 μm to 500 μm.

In one embodiment, the fluid coolant includes a liquid or a gas.

In one embodiment, the cap includes a heat sink that includes a plurality of fins.

In one embodiment, the system further includes a flow disturbance structure on the integrated device die or on an inner surface of the cap that is configured to disturb flow of the fluid coolant in the cavity.

In one embodiment, the system further includes a thermoelectric element that is coupled to the cap or the integrated device die.

In one embodiment, the system further includes a second integrated device die that is disposed in the cavity. The second integrated device die can be directly bonded to the carrier. The second integrated device die can be stacked on the integrated device die.

In one aspect, a method for forming an integrated device package is disclosed. The method can include providing a carrier, and bonding a cap to the carrier. The carrier and the cap at least partially define a cavity in which a fluid coolant is disposed at least during operation of the integrated device package. The method can include directly bonding an integrated device die to the carrier. The integrated device die can be disposed in the cavity.

In one embodiment, the method further includes forming a fluid inlet that is configured to convey the fluid coolant into the cavity, and forming a fluid outlet that is configured to remove the fluid coolant from the cavity. The method can further include supplying the fluid coolant into the cavity. The supplying the fluid coolant can include delivering the fluid coolant through the fluid inlet.

In one aspect, an integrated device package is disclosed. The integrated device package can include a carrier, and a cap that is bonded to the carrier. The carrier and the cap at least partially define a cavity in which a fluid coolant is disposed at least during operation of the integrated device package. The integrated device package can include an integrated device die that is disposed in the cavity and bonded to the carrier. At least a portion of the integrated device die is in contact with the fluid coolant at least during operation of the integrated device package. The integrated device package can include an inorganic material layer that is disposed at least on a portion of the carrier. At least one of the cap and the integrated device die is directly bonded to the carrier without an intervening adhesive.

In one aspect, an integrated device package is disclosed. The integrated device package can include a carrier that has a first conductive feature a first non-conductive region. The integrated device package can include a cap that is bonded to the carrier. The carrier and the cap at least partially defining a cavity configured to receive a fluid coolant. The integrated device package can include an opening that is configured to convey the fluid coolant into or remove the fluid coolant from the cavity. The integrated device package can include an integrated device die that has a second conductive feature and a second non-conductive region. The integrated device die is disposed in the cavity. The second conductive feature is directly bonded to the first conductive feature of the carrier, and the second non-conductive region is directly bonded to the first non-conductive region of the carrier.

In one embodiment, a distance between the conductive feature of the integrated device die and an edge of the integrated device die is between 50 μm to 500 μm.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An integrated device package comprising:
a carrier;
a cap directly bonded to the carrier without an intervening adhesive, the carrier and the cap at least partially defining a cavity configured to receive a coolant; and
an inorganic material layer disposed at least on a portion of the carrier, at least a portion of the inorganic material layer being exposed to the cavity and configured to contact the coolant.

2. The package of claim 1, further comprising an integrated device die that is disposed in the cavity and bonded to the carrier.

3. The package of claim 2, wherein the carrier comprises an interposer or a printed circuit board (PCB).

4. (canceled)

5. The package of claim 2, wherein the cap comprises silicon, glass, plastic, or metal, and the cap is bonded to the carrier by way of a glue, eutectic, or solder.

6. (canceled)

7. The package of claim 2, wherein the inorganic material layer is further disposed on the integrated device die.

8. The package of claim 2, wherein the integrated device die is directly bonded to the carrier.

9. The package of claim 8, wherein the integrated device die comprises a conductive feature and a non-conductive region, wherein the conductive feature is directly bonded to a corresponding conductive feature of the carrier and the non-conductive region is directly bonded to a corresponding non-conductive region of the carrier.

10. The package of claim 9, wherein a distance between the conductive feature of the integrated device die and an edge of the integrated device die is between 50 μm to 500 μm.

11. The package of claim 9, wherein the non-conductive region of the carrier comprises the inorganic material layer.

12. (canceled)

13. (canceled)

14. (canceled)

15. The package of claim 2, wherein the cap comprises a coolant inlet and a coolant outlet, wherein the coolant is configured to flow from the coolant inlet to the coolant outlet in the cavity.

16. (canceled)

17. The package of claim 2, wherein a leg of the cap that is bonded to the carrier has a width in a range of 100 μm to 5 mm.

18. The package of claim 2, wherein the coolant comprises a liquid or a gas.

19. (canceled)

20. The package of claim 2, further comprising a flow disturbance structure on the integrated device die or on an inner surface of the cap configured to disturb flow of the coolant in the cavity.

21. The package of claim 2, further comprising a thermoelectric element coupled to the cap or the integrated device die.

22. (canceled)

23. (canceled)

24. (canceled)

25. (canceled)

26. An integrated device package comprising:
a carrier;
a cap bonded to the carrier, the carrier and the cap at least partially defining a cavity configured to receive a fluid coolant;
an opening configured to convey the fluid coolant into or remove the fluid coolant from the cavity; and
an integrated device die disposed in the cavity and directly bonded to the carrier.

27. The package of claim 26, further comprising an inorganic material layer disposed at least on a portion of the carrier, wherein the inorganic material is configured to contact the fluid coolant.

28. (canceled)

29. (canceled)

30. (canceled)

31. (canceled)

32. (canceled)

33. The package of claim 26, wherein further comprising an inorganic material layer disposed on the integrated device die.

34. The package of claim 26, wherein the integrated device die comprises a conductive feature and a non-conductive region, wherein the conductive feature is directly bonded to a corresponding conductive feature of the carrier and the non-conductive region is directly bonded to a corresponding non-conductive region of the carrier.

35-77. (canceled)

78. An integrated device package comprising:
a carrier having a first conductive feature and a first non-conductive region;
a cap bonded to the carrier, the carrier and the cap at least partially defining a cavity configured to receive a fluid coolant;
an opening configured to convey the fluid coolant into or remove the fluid coolant from the cavity; and
an integrated device die having a second conductive feature and a second non-conductive region, the integrated device die disposed in the cavity, the second conductive feature being directly bonded to the first conductive feature of the carrier, and the second non-conductive region being directly bonded to the first non-conductive region of the carrier.

79. The integrated device package of claim 78, wherein a distance between the conductive feature of the integrated device die and an edge of the integrated device die is between 50 μm to 500 μm.
